(19) United States
(12) Patent Application Publication
(10) Pub. No.: US 2026/0096381 A1
(43) Pub. Date: Apr. 2, 2026

(54) PROCESSING LIQUID ADJUSTMENT APPARATUS, SUBSTRATE PROCESSING APPARATUS, PROCESSING LIQUID ADJUSTMENT METHOD

(71) Applicant: SHIBAURA MECHATRONICS CORPORATION, Yokohama-shi (JP)

(72) Inventors: Kentaro OKADA, Yokohama-shi (JP); Hiroki KOYAMA, Yokohama-shi (JP); Katsunori MOCHIZUKI, Yokohama-shi (JP)

(73) Assignee: SHIBAURA MECHATRONICS CORPORATION, Yokohama-shi (JP)

(21) Appl. No.: 19/343,561

(22) Filed: Sep. 29, 2025

(30) Foreign Application Priority Data
Sep. 30, 2024 (JP) 2024-171559

(51) Int. Cl. H01L 21/67; G05D 23/19; H01L 21/311

(52) U.S. Cl. CPC H10P 72/0422; G05D 23/1917; H10P 50/283

(57) ABSTRACT

According to one embodiment, provided is a processing liquid adjustment apparatus connected to the processing apparatus for a substrate and includes a new liquid supply controller that controls a processing liquid supplier to supply a processing liquid to an adjustment tank, a silica supply controller that controls a silica supplier to supply silica to the processing liquid in the adjustment tank, a heating controller that controls a heating unit to raise the temperature of the processing liquid in the adjustment tank to a first temperature, a temperature maintenance controller that controls the heating unit to maintain the temperature of processing liquid in the adjustment tank to which silica has been supplied at the first temperature, and a cooling controller that controls a cooler to lower the temperature of the processing liquid in the adjustment tank to the second temperature that is lower than the first temperature after the maintenance of the first temperature by the temperature maintenance controller.

### CROSS-REFERENCE TO RELATED APPLICATION

This application is based upon and claims the benefit of priority from Japan Patent Application No. 2024-171559, filed on September 30, 2024, the entire contents of which are incorporated herein by reference.

### FIELD

The embodiments of the present disclosure relate to a processing liquid adjustment apparatus, a substrate processing apparatus and a processing liquid adjustment method.

### BACKGROUND

In manufacturing processes for semiconductors and flat panel displays, a processing apparatus is used to form desired circuit patterns on a film formed on a surface to be processed of substrates such as semiconductor wafers and glass substrates by supplying processing liquid for etching and performing etching.

There is a processing apparatus to selectively etch the nitride film by supplying a phosphoric acid solution as a processing liquid to the substrate such as a semiconductor wafer on which the nitride film and oxide film are formed. In such a processing apparatus, an etching rate is adjusted by heating the phosphoric acid solution to be supplied on the substrate.

### SUMMARY

### PROBLEMS TO BE SOLVED BY INVENTION

In such a processing apparatus, it may be necessary to perform etching at a low etching rate by supplying a phosphoric acid solution that is heated to a relatively low temperature on the substrate. Furthermore, when the concentration of silica (SiO₂) in the phosphoric acid solution is high, the selectivity ratio of the film to be removed by etching increases, so silica may be supplied to the phosphoric acid solution to dissolve silica. However, the saturated solubility of silica increases as the temperature of the phosphoric acid solution increases. Therefore, silica cannot be rapidly dissolved in the phosphoric acid solution with a relatively low temperature, and it takes a long time to prepare the phosphoric acid solution at the desired temperature in which silica is dissolved.

The objective of the embodiments of the present disclosure is to provide a processing liquid adjustment apparatus, a substrate processing apparatus and a processing liquid adjustment method that can obtain the phosphoric acid solution at the desired temperature in which silica is dissolved in a short time.

### MEANS TO SOLVE THE PROBLEM

A processing liquid adjustment apparatus of the present embodiment adjusts a processing liquid supplied to a processing apparatus that processes a substrate using a phosphoric acid solution that is the processing liquid and includes: an adjustment tank that stores the processing liquid; a processing liquid supplier that supplies the processing liquid to the adjustment tank; a heater that heats the processing liquid; a silica supplier that supplies silica to the processing liquid in the adjustment tank; a cooler that lowers a temperature of the processing liquid in the adjustment tank; and a controller that controls the processing liquid supplier, the heater, the silica supplier and the cooler, in which the controller includes a new liquid supply controller that controls the processing liquid supplier to supply the processing liquid to the adjustment tank, a silica supply controller that controls the silica supplier to supply silica to the processing liquid in the adjustment tank, a heating controller that controls the heater to raise the temperature of the processing liquid in the adjustment tank to a first temperature, a temperature maintenance controller that controls the heater to maintain the temperature of processing liquid in the adjustment tank to which the silica has been supplied at the first temperature, and a cooling controller that controls the cooler to lower the temperature of the processing liquid in the adjustment tank to a second temperature that is lower than the first temperature after a maintenance of the first temperature by the temperature maintenance controller.

A substrate processing apparatus of the embodiment of the present disclosure includes the processing apparatus and the processing liquid adjustment apparatus.

A processing liquid adjustment method of the present embodiment adjusts a processing liquid supplied to a processing apparatus that processes a substrate using a phosphoric acid solution that is the processing liquid and includes: a processing liquid supply process of supplying the processing liquid to an adjustment tank; a heating process of raising a temperature of the processing liquid in the adjustment tank to a first temperature; a silica supply process of supplying silica to the processing liquid in the adjustment tank; a temperature maintenance process of maintaining the temperature of the processing liquid in the adjustment tank to which the silica has been supplied at the first temperature, and a cooling process of lowering the temperature of the processing liquid in the adjustment tank to a second temperature that is lower than the first temperature by a cooler after the temperature maintenance process.

### EFFECT OF INVENTION

The embodiment of the present disclosure can obtain the phosphoric acid solution at the desired temperature in which silica is dissolved in a short time.

### BRIEF DESCRIPTION OF DRAWINGS

FIG. 1 is a simplified configuration diagram illustrating the processing apparatus and the processing liquid adjustment apparatus of the first embodiment.

FIG. 2 is a flowchart illustrating the processing liquid adjustment procedures in the processing liquid adjustment apparatus of the first embodiment.

FIG. 3 is a simplified configuration diagram illustrating the processing apparatus and the processing liquid adjustment apparatus of the second embodiment.

FIG. 4 is a flowchart illustrating the processing liquid adjustment apparatus and the processing liquid adjustment procedures of the second embodiment.

FIG. 5 is a simplified configuration diagram illustrating the modified example of the processing apparatus and the processing liquid adjustment apparatus.

### EMBODIMENTS

Hereinafter, embodiments of the present disclosure will be described with reference to the figures.

### First Embodiment

Firstly, the first embodiment is described.

### SUMMARY

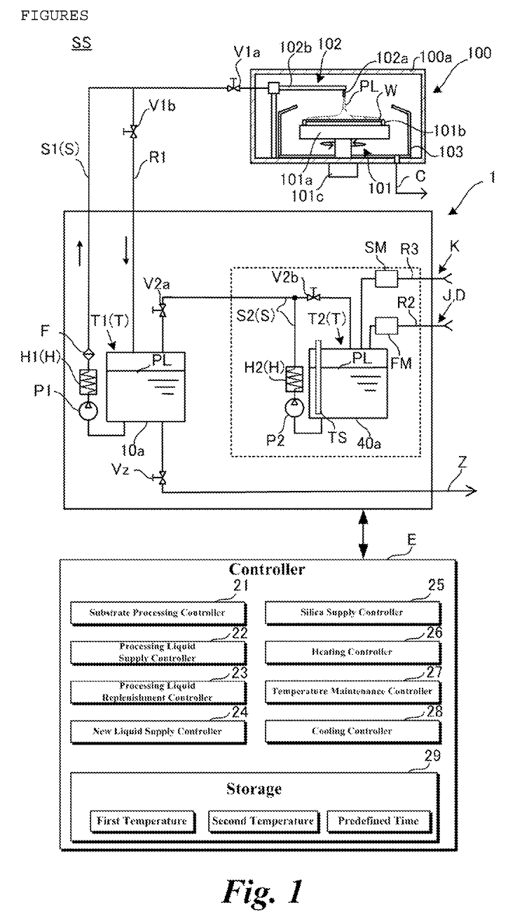

As illustrated in FIG. 1, a processing liquid adjustment apparatus 1 of the present embodiment is an apparatus to adjust a processing liquid PL supplied to a processing apparatus 100 that processes a substrate W. The processing liquid adjustment apparatus may also be regarded as a processing liquid adjustment apparatus to supply the processing liquid PL to the processing apparatus 100. The processing liquid adjustment apparatus 1 dissolves silica (SiO2) in the processing liquid PL and adjust the processing liquid PL to the target temperature. In the present embodiment, when silica is dissolved, the temperature of the processing liquid PL is adjusted to a first temperature with a relatively high temperature, and when supplying the processing liquid PL to the processing apparatus 100, the temperature of the processing liquid PL is adjusted to a second temperature with a relatively low temperature. Note that, in the descriptions below, an apparatus to process the substrate W by supplying the processing liquid PL from the processing liquid adjustment apparatus 1 to the processing apparatus 100 is called a substrate processing apparatus SS.

### Processing Apparatus

For example, the processing apparatus 100 is a single-wafer type etching apparatus to remove unnecessary films and leave circuit patterns by supplying the processing liquid PL on the rotating substrate W. In the present embodiment, an aqueous solution containing phosphoric acid (H3PO4) (hereinafter referred to as the phosphoric acid solution) is used as the processing liquid PL. It is necessary to heat the phosphoric acid solution to ensure a processing rate, and in general, the phosphoric acid solution is used at about 160 °C. However, in the present embodiment, the phosphoric acid is used at lower temperature such as about 140 °C.

Furthermore, when etching the substrate W that is a semiconductor wafer, the selectivity ratio in etching for specific materials can be increased by supplying a silica solution to the phosphoric acid solution and dissolving silica. For example, when it is desired to remove a silicon nitride film (SiN) and maintain a silicon oxide film (SiO₂), the phosphoric acid solution containing dissolved silica is used.

The processing apparatus 100 is a single-wafer type apparatus that processes the substrate W one by one using the processing liquid PL. The processing apparatus 100 includes a rotation unit 101, a supply unit 102, and a collection unit 103, which are configured in a chamber 100a that is a container. The rotation unit 101 includes a rotation body 101a and a drive source 101c. The rotation body 101a is a rotation table that holds the periphery of the substrate W by a holding unit 101b such as chuck pins and that rotates around an axis orthogonal to the surface of the substrate W to be processed. The drive source 101c is a motor to rotate the rotation body 101a.

The supplying unit 102 includes a nozzle 102a and an arm 102b. The nozzle 102a is a discharging unit that discharges the processing liquid PL toward the surface of the substrate W to be processed. The arm 102b is provided to the tip of the nozzle 102a and swings the nozzle 102a between a position above the center of the rotation body 101a and a position where the nozzle 102a is retracted from above the rotation body 101a. The nozzle 102a is connected to the processing liquid adjustment apparatus 1 via a supply piping S1 that is described later, and the processing liquid PL is supplied from the processing liquid adjustment apparatus 1 to the nozzle 102a.

The collection unit 103 is provided so as to surround the rotation body 101a and is a housing to collect the processing liquid PL that has been supplied from the nozzle 102a to the surface of the substrate W to be processed and that has leaked from the end surface of the substrate W, from the bottom of the collection unit 103. Openings are provided to the bottom of the collection unit 103 and the bottom of the chamber 100a and are connected to a collection path for the processing liquid PL via a collection piping C.

### Processing Liquid Adjustment Apparatus

The processing liquid adjustment apparatus 1 adjusts the processing liquid PL supplied to the processing apparatus 100. The processing liquid adjustment apparatus 1 may also be regarded as a processing liquid supply apparatus to supply the processing liquid PL to the processing apparatus 100. Although omitted in FIG. 1, a plurality of the processing apparatuses 1 is provided to one processing liquid adjustment apparatus 1.

The processing liquid adjustment apparatus 1 includes a tank T, a supply path S, a heater H, and a controller E. The tank T stores the processing liquid PL. The tank T includes a plurality of tanks, such as a supply tank T1 and an adjustment tank T2. Hereinafter, the tanks T1 and T2 are described as the tank T unless otherwise distinguished.

The supply path S connects the tanks T1 and T2 so that the processing liquid PL can flow between the tanks T1 and T2 and supplies the processing liquid PL to the processing apparatus 100 sequentially via the tanks T1 and T2. The supply path S includes the supply piping S1 and a delivery piping S2. The heater H heats the processing liquid PL. The heater H includes heating units H1 and H2.

### Supply Tank

The supply tank T1 includes a container 10a and stores the processing liquid PL supplied to the processing apparatus 100 in the container 10a. The container 10a is formed from materials that are resistant to corrosion by the processing liquid PL. The supply tank T1 is connected to the supply piping S1 and a return piping R1. The supply piping S1 is a piping that is connected to the bottom of the container 10a and supplies the processing liquid PL to the supply unit 102 of the processing apparatus 100.

A pump P1, a heating unit H1, a filter F and a valve V1a are provided on the path of the supply piping S1. The pump P1 sucks the processing liquid PL from the bottom of the supply tank T1 and sends the processing liquid PL to the supply unit 102. The heating unit H1 is provided downstream of the pump P1 and heats the processing liquid PL sent from the pump P1 to the predefined target temperature.

Note that, here, in the flow from the supply tank T1 to the processing apparatus 100, the side of the supply tank T1 is upstream and the side of the processing apparatus 100 is downstream. An unillustrated temperature sensor is provided downstream of the heating unit H1, and the output of the heating unit H1 is adjusted based on the temperature of the processing liquid PL measured by the temperature sensor. For example, the temperature sensor is a thermistor. The processing liquid PL that has been heated to the target temperature by the heating unit H1 is supplied to the supply unit 102 of the processing apparatus 100.

The filter F is provided downstream of the heating unit H1 and removes impurities from the processing liquid PL flowing to the supply piping S1. The valve V1a is provided downstream of the filter F and switches whether or not to supply the processing liquid PL to the processing apparatus 100.

The return piping R1 branches from the supply piping S1 upstream of the valve V1a and is connected to the supply tank T1. A valve V1b is provided to the return piping R1. When it is not required to supply the processing liquid PL to the substrate W, the valve V1a is closed and the valve V1b is opened so that the processing liquid PL flowing in the supply piping S1 is returned to the supply tank T1 via the return piping R1. That is, a circulation path is formed by the return piping R1 and the supply piping S1. In this circulation path, the temperature of the processing liquid PL in the supply tank T1 is maintained at the target temperature by heating the processing liquid PL with the heating unit H1. In the present embodiment, the temperature of the processing liquid PL in the supply tank T1 is maintained at 140 °C.

Also, although not illustrated, a liquid level sensor to detect a liquid surface is provided to the supply tank T1. Accordingly, whether the processing liquid PL in the supply tank T1 is less than a certain amount or not can be detected. Note that a heating unit that heats the processing liquid PL to the target temperature may be installed inside the container 10a of the supply tank T1.

Furthermore, a piping with a valve Vz is connected to the bottom of the supply tank T1 and joins a discharge path Z that is a common piping. The discharge path Z is connected to a factory's waste liquid line.

### Adjustment Tank

The adjustment tank T2 includes a container 40a and stores a newly prepared processing liquid PL in the container 40a. The container 40a is formed from materials that are resistant to corrosion by the processing liquid PL. The adjustment tank T2 is connected to a new liquid piping R2, an addition piping R3 and a delivery piping S2.

The new liquid piping R2 is a piping to supply the processing liquid PL from the unillustrated supply source of the processing liquid PL to the adjustment tank T2. The temperature of the processing liquid PL supplied from the new liquid piping R2 is lower than or equal to the second temperature and in the present embodiment, is normal temperature. A flow meter FM to measure the flow rate of the supplied processing liquid PL is provided to the new liquid piping R2. The new liquid piping R2 forms a processing liquid supplier J that supplies the processing liquid PL to the adjustment tank T2. Note that, in the description below, the processing liquid PL supplied to the adjustment tank T2 by the processing liquid supplier J is called a new liquid. Furthermore, the processing liquid supplier J forms a cooler D that lowers the temperature of the processing liquid PL in the adjustment tank T2.

The addition piping R3 is a piping to supply a silica liquid from an unillustrated supply source of the silica liquid to the adjustment tank T2. The addition piping R3 forms a silica supplier K that supplies silica to the adjustment tank T2. The silica supplier K of the present embodiment supplies silica as a silica liquid that is water containing silica particles. The selectivity of etching for the silicon nitride film can be improved by dissolving silica contained in the silica liquid in the processing liquid PL (phosphoric acid solution). A flow meter SM to measure the flow rate of the supplied silica liquid is provided to the addition piping R3.

The delivery piping S2 delivers the processing liquid PL in the adjustment tank T2 to the supply tank T1. The delivery piping S2 is connected to the bottom of the container 40a. A pump P2 and a heating unit H2 are provided to the delivery piping S2. The pump P2 sucks the processing liquid PL from the bottom of the adjustment tank T2 and sends the processing liquid PL to the supply tank T1. The heating unit H2 is provided downstream of the pump P2 and heats the processing liquid PL sent from the pump P2 to the predefined target temperature. Note that, here, in the flow from the bottom of the adjustment tank T2 to the supply tank T1 or the upper portion of the adjustment tank T2, the bottom side of the adjustment tank T2 is upstream and the upper side of the supply tank T1 or the adjustment tank T2 is downstream.

The delivery piping S2 is divided into a delivery path to deliver the processing liquid PL to the supply tank T1 and a return path that returns to the adjustment tank T2. A valve V2a is provided to the delivery path to the supply tank T1. The valve V2a switches whether or not to deliver the processing liquid PL to supply tank T1. A valve V2b is provided to the return path to the adjustment tank T2. The valve V2b switches whether or not to return the processing liquid PL to adjustment tank T2.

The valve V2a is closed and the valve V2b is opened so that the processing liquid PL that has been heated by the heating unit H2 returns to the adjustment tank T2 and circulates. Accordingly, the heating unit H2 heats the processing liquid PL in the adjustment tank T2 to the target temperature. In the present embodiment, as described later, silica is dissolved by supplying the silica liquid to the adjustment tank T2 from the addition piping R3 while heating the processing liquid PL in the adjustment tank T2 to the first temperature that is the target temperature. In the present embodiment, the first temperature is 162 °C. Then, the temperature of the processing liquid PL is lowered to the second temperature that is the target temperature by supplying the processing liquid PL at normal temperature to the adjustment tank T2 from the new liquid piping R2. Furthermore, the processing liquid PL that has been cooled to the second temperature is heated by the heating unit H2 to maintain the second temperature. In the present embodiment, the second temperature is 147 °C.

Note that it is sufficient if the second temperature is lower than the first temperature and is more than or equal to the temperature to process the substrate W. The difference between the first temperature and the second temperature is preferably smaller in view of cooling the processing liquid PL. Meanwhile, the processing liquid PL at the second temperature in the adjustment tank T2 is supplied to the supply tank T1 storing the processing liquid PL to be supplied to the processing apparatus 100. Therefore, the second temperature is preferably closer to the temperature to process the substrate W, so that the temperature fluctuation of the processing liquid PL in the supply tank T1 is smaller. In view of this, in the present embodiment, the second temperature is 147 °C that is lower than the first temperature and more than or equal to the temperature to process the substrate W.

When the temperature of the processing liquid PL in the adjustment tank T2 is lowered to the second temperature and the amount of the processing liquid PL in the supply tank T1 is below a certain amount, the valve V2b is closed and the valve V2a is opened to deliver the predefined amount of the processing liquid PL in the adjustment tank T2 to the supply tank T1. Accordingly, the processing liquid PL that has been supplied to the processing apparatus 100 and used for processing is replenished. The amount of new liquid corresponding to the amount of the processing liquid PL delivered to the supply tank T1 is supplied to the adjustment tank T2 from the new liquid piping R2. Then, next heating is performed.

A temperature sensor TS to measure the temperature of the processing liquid PL is provided in the adjustment tank T2. The output of the heating unit H2 is adjusted based on the temperature of the processing liquid PL measured by the temperature sensor TS. Furthermore, whether the processing liquid PL in the adjustment tank T2 has reached the target temperature or not can be determined. For example, the temperature sensor TS is a thermistor.

Also, although not illustrated, a liquid level sensor to detect a liquid surface is provided to the adjusted tank T2. Accordingly, whether the processing liquid PL in the adjustment tank T2 is within a certain amount or not can be detected, and whether to supply the processing liquid PL from the new liquid piping R2 can be determined, Note that a heating unit for heating the processing liquid PL to the target temperature may be installed in the adjustment tank T2. That is, the heater H is not limited to an aspect in which the heater H is arranged in the circulation path.

### Controller

The controller E controls each unit of the substrate processing apparatus SS. The controller E includes a processor that executes programs, a memory that stores various information such as programs and operation conditions, and a driving circuit that drives each component, to achieve various functions of the substrate processing apparatus SS. Note that, the controller E includes an input device to input information and a display device to display information.

The controller E includes a substrate processing controller 21, a processing liquid supply controller 22, a processing liquid replenishment controller 23, a new liquid supply controller 24, a silica supply controller 25, a heating controller 26, a temperature maintenance controller 27, a cooling controller 28 and a storage 29.

The substrate processing controller 21 controls each of the processing apparatus 100 and the processing liquid adjustment apparatus 1 to perform processing of the substrate W. That is, the substrate processing controller 21 controls the transportation of the substrate W in and out of the chamber 100a, the holding of the substrate W by the holding unit 101b, the rotation of the rotation body 101a by the drive source 101c and the swinging of the nozzle 102a by the arm 102b.

The processing liquid supply controller 22 controls whether or not to supply the processing liquid PL to the processing apparatus 100. That is, the processing liquid supply controller 22 switches the opening and closing of the valves V1a and V1b to switch whether to supply or stop supplying the processing liquid PL. The processing liquid replenishment controller 23 controls whether or not to replenish the processing liquid PL to the supply tank T1 from the adjustment tank T2. That is, the processing liquid replenishment controller 23 switches the opening and closing of the valves V2a and V2b to switch whether to replenish or stop replenishing the processing liquid PL to the supply tank T1 from the adjustment tank T2. The new liquid supply controller 24 controls the processing liquid supplier J to supply the processing liquid PL that is the new liquid to the adjustment tank T2. The new liquid supply controller 24 controls the processing liquid supplier J to stop supplying the new liquid when the accumulated value of the flow rate measured by the flow meter FM reaches the predetermined value since the processing liquid supplier J starts supplying the processing liquid PL to the adjustment tank T2.

The silica supply controller 25 controls the silica supplier K to supply silica to the processing liquid PL in the adjustment tank T2. The silica supply controller 25 controls the silica supplier K to supply silica so that the concentration of silica contained in the processing liquid PL in the adjustment tank T2 becomes lower than the saturated solubility of silica at the temperature of the processing liquid PL supplied to the processing apparatus 100. The silica supply controller 25 controls the silica supplier K to stop supplying silica when the accumulated value of the flow rate measured by the flow meter SM reaches the predetermined value since the silica supplier K starts supplying silica to the adjustment tank T2. The heating controller 26 controls the heating unit H2 to raise the temperature of the processing liquid PL in the adjustment tank T2 to the first temperature. For example, the heating controller 26 controls the heating unit H2 to heat the processing liquid PL in the adjustment tank T2 until the temperature of the processing liquid PL measured by the temperature sensor TS becomes the first temperature.

The temperature maintenance controller 27 controls the heating unit H2 to maintain the temperature of the processing liquid PL in the adjustment tank T2 to which silica has been supplied at the first temperature. The first temperature is maintained for the predefined time until silica dissolves in the processing liquid PL. Furthermore, the temperature maintenance controller 27 controls the heating unit H2 to maintain the temperature of the processing liquid PL, in which silica is dissolved, in the adjustment tank T2 at the second temperature. The second temperature is maintained from when the temperature of the processing liquid PL in the adjustment tank T2 is lowered to the second temperature until the temperature of the processing liquid PL in the adjustment tank T2 is heated to the first temperature.

The cooling controller 28 controls the cooler D to lower the temperature of the processing liquid PL in the adjustment tank T2 to the second temperature that is lower than the first temperature after the temperature of the processing liquid PL has been maintained at the first temperature by the temperature maintenance controller 27. In the present embodiment, the cooling controller 28 controls the processing liquid supplier J that is the cooler D to cool the processing liquid PL by supplying the processing liquid PL at temperature lower than or equal to the second temperature to the adjustment tank T2. For example, the cooling controller 28 controls the processing liquid supplier J to stop supplying the processing liquid PL when the accumulated value of the flow rate of the processing liquid PL measured by the flow meter FM reaches the accumulated value of the flow rate that cools the processing liquid PL in the adjustment tank T2 to the second temperature. Such a flow rate of the processing liquid PL at normal temperature that cools the processing liquid PL in the adjustment tank T2 to the second temperature is determined based on the first temperature, the difference between the first temperature and the second temperature, and the amount of the processing liquid PL in the adjustment tank T2 maintained at the first temperature.

The storage 29 is formed from a memory and stores the first temperature and the second temperature that are the target temperature, and the predefined time. Workers can input the desired value for the first temperature, the second temperature and the predefined time using an input device.

### Action

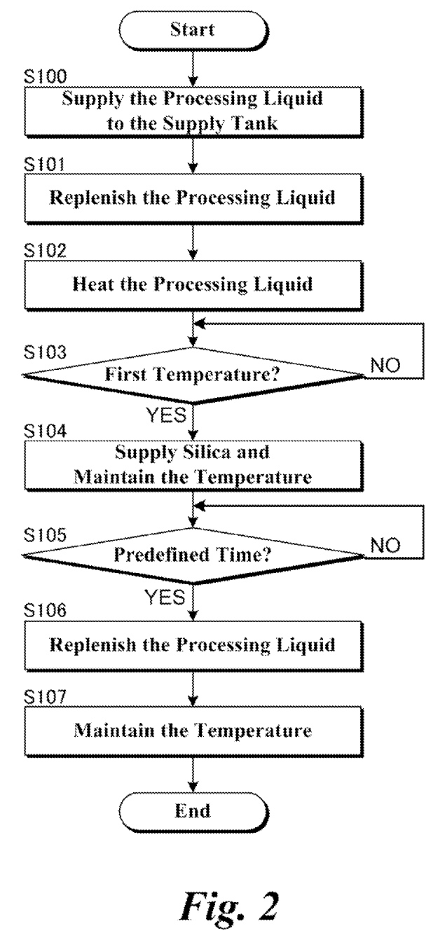

The action of the substrate processing apparatus SS of the above present embodiment is described referring to the flowchart of FIG. 2, in addition to FIG. 1. Note that the substrate processing method to process the substrate W, the processing liquid supply method to supply the processing liquid PL and the processing liquid adjustment method to adjust the processing liquid PL by the following schemes are also aspects of the present embodiment.

### Substrate Processing

Firstly, the substrate processing by the processing apparatus 100 is described. The substrate W that is a processing target is transported onto the rotation body 101a by a transportation robot and is held by the holding unit 101b. The drive source 101c rotates the substrate W by rotating the rotation body 101a. The processing liquid PL adjusted by the processing liquid adjustment apparatus 1 is supplied to the surface to be processed of the substrate W from the nozzle 102a when the valve V1a is opened to perform etching.

When the predetermined processing time elapses, the valve V1a is closed to stop supplying the processing liquid PL. Then, the rotation of the substrate W is stopped, and the substrate W released from the holding unit 101b is transported out of the chamber 100a by the transportation robot.

### Adjustment of Processing Liquid

Next, the adjustment process of the processing liquid PL in the processing liquid adjustment apparatus 1 is described. Before the processing liquid PL of the supply tank T1 is supplied to the processing apparatus 100, the valve V1a is closed and the valve V1b is opened, and the heating unit H1 heats the processing liquid PL circulating in the supply piping S1, the return piping R1 and the supply tank T1 to maintain the temperature of the processing liquid PL at the target temperature. Then, the valve V1b is closed and the valve V1a is opened at the time of the processing in the processing apparatus 100 to supply the processing liquid PL of the supply tank T1 to the processing apparatus 100 as described above.

Hereinafter, the process of heating the processing liquid PL in the adjustment tank T2 to dissolve silica and then cooling the processing liquid PL is described according to the flowchart of FIG. 2. The valve V2a is closed and the valve V2b is opened, and the heating unit H2 heats the processing liquid PL circulating in the delivery piping S2 and the adjustment tank T2 to maintain the temperature of the processing liquid PL at the second temperature. Furthermore, silica is dissolved in the processing liquid PL in the adjustment tank T2. Then, when the processing liquid PL is supplied to the processing apparatus 100 and the amount of the processing liquid PL in the supply tank T1 is below a certain amount, the valve V2a is opened and the valve V2b is closed to supply the processing liquid PL of the adjustment tank T2 to the supply tank T1 (Step S100).

Accordingly, when the processing liquid PL in the adjustment tank T2 is supplied to the supply tank T1, the valve V2a is closed and the valve V2b is opened. Then, the processing liquid PL at normal temperature is supplied from the new liquid piping R2 to the adjustment tank T2 to replenish the processing liquid PL (processing liquid supply process: Step S101). At this time, a part of the total amount of the processing liquid PL that needs to be replenished, that is, a part of the total replenishment amount is supplied, and the remaining part is used in the cooling process. For example, when the total replenishment amount is 7.5 L, 3 L is supplied. Such a supply amount is controlled based on the accumulated value of the flow rate measured by the flow meter FM since the supply of the processing liquid PL to the adjustment tank T2 started. Note that the normal temperature here is the temperature of the processing liquid PL in the atmosphere with constant temperature where the substrate processing apparatus SS according to the present embodiment is installed (hereinafter, the normal temperature is within the range of 20±10 °C).

The valve V2a is closed and the valve V2b is opened, and the heating unit H2 heats the processing liquid PL circulating in the delivery piping S2 and the adjustment tank T2 (heating process: Step S102). Accordingly, the temperature of the processing liquid PL measured by the temperature sensor TS is raised to the first temperature (Step S103, NO). For example, the processing liquid PL is heated to 162 °C that is the first temperature.

When the temperature of the processing liquid PL is raised to the first temperature (Step S103, YES), the silica liquid is supplied to the processing liquid PL in the adjustment tank T2 from the addition piping R3 (silica supply process: Step S104). At this time, the supply amount of silica is the predefined amount relative to the total replenish amount of the processing liquid PL. For example, said supply amount is an amount in which silica does not precipitate at the temperature of the processing liquid PL supplied to the processing apparatus 100. That is, said supply amount is an amount in which the concentration of silica contained in the processing liquid PL in the adjustment tank T2 becomes lower than the saturated solubility of silica at the temperature of the processing liquid PL supplied to the processing apparatus 100. Such a supply amount is controlled based on the accumulated value of the flow rate measured by the flow meter SM since the supply of silica to the adjustment tank T2 started. The heating unit H2 continues heating the processing liquid PL to maintain the first temperature until the predefined time for silica supplied as the silica liquid dissolves elapses (temperature maintenance process: Step S105, NO).

When the predefined time elapses (step S105, YES) the processing liquid PL at normal temperature is supplied from the new liquid piping R2 to the adjustment tank T2 (cooling process: Step S106). At this time, the remaining part of the total amount of the processing liquid PL that needs to be replenished is supplied. For example, when 3 L of the processing liquid PL has been supplied in Step S101, 4.5 L is supplied. Such a supply amount is controlled based on the accumulated value measured by the flow meter FM. Furthermore, the supply amount of the processing liquid PL at normal temperature is set to an amount that can lower the temperature of the processing liquid PL to the second temperature by supplying the processing liquid PL in the adjustment tank T2. Therefore, the temperature of the processing liquid PL is lowered to the second temperature by supplying the processing liquid PL at normal temperature to the adjustment tank T2. Note that the temperature of the supplied processing liquid PL may not be normal temperature if the temperature is lower than or equal to the second temperature as long as the processing liquid PL that has been heated for dissolving silica can be cooled to the second temperature that is close to the temperature to process the substrate W. In this case, the supply amount of the processing liquid PL at normal temperature is set to an amount that can lower the temperature of the processing liquid PL to the second temperature by supplying the processing liquid PL in the adjustment tank T2.

Then, until the processing liquid PL is delivered to the supply tank T1 after the temperature of the processing liquid PL in the adjustment tank T2 is lowered to the second temperature, the heating unit H2 maintains the temperature of the processing liquid PL circulating in the delivery piping S2 and the adjustment tank T2 at the second temperature as described above (Step S107).

### Effect

(1) the processing liquid adjustment apparatus 1 of the present embodiment adjusts the processing liquid PL supplied to the processing apparatus 100 that processes the substrate W using the phosphoric acid solution that is the processing liquid PL and includes: the adjustment tank T2 that stores the processing liquid PL; the processing liquid supplier J that supplies the processing liquid PL to the adjustment tank T2; the heating unit H2 that heats the processing liquid PL; the silica supplier K that supplies silica to the processing liquid PL in the adjustment tank T2; the cooler D that lowers the temperature of the processing liquid PL in the adjustment tank T2; and a controller E that controls the processing liquid supplier J, the heating unit H2, the silica supplier K and the cooler D.

The controller E includes the new liquid supply controller 24 that controls the processing liquid supplier J to supply the processing liquid PL to the adjustment tank T2, the silica supply controller 25 that controls the silica supplier K to supply silica to the processing liquid PL in the adjustment tank T2, the heating controller 26 that controls the heating unit H2 to raise the temperature of the processing liquid PL in the adjustment tank T2 to the first temperature, the temperature maintenance controller 27 that controls the heating unit H2 to maintain the temperature of processing liquid PL in the adjustment tank T2 to which silica has been supplied at the first temperature, and the cooling controller 28 that controls the cooler D to lower the temperature of the processing liquid PL in the adjustment tank T2 to the second temperature that is lower than the first temperature after the maintenance of the first temperature by the temperature maintenance controller 27.

The processing liquid adjustment method of the present embodiment adjusts the processing liquid PL supplied to the processing apparatus 100 that processes the substrate W using the phosphoric acid solution that is the processing liquid PL and includes: a processing liquid supply process of supplying the processing liquid PL to the adjustment tank T2; a heating process of raising the temperature of the processing liquid PL in the adjustment tank T2 to the first temperature; the silica supply process of supplying silica to the processing liquid PL in the adjustment tank T2; the temperature maintenance process of maintaining the temperature of the processing liquid PL in the adjustment tank T2 to which silica has been supplied at the first temperature; and the cooling process of lowering the temperature of the processing liquid PL in the adjustment tank T2 to the second temperature that is lower than the first temperature by the cooler D after the temperature maintenance process.

Therefore, the silica liquid containing silica is supplied to the processing liquid PL that is the phosphoric acid solution in the adjustment tank T2, and the processing liquid PL is heated and maintained at the first temperature which is the temperature which is relatively high and to which silica easily dissolves. Accordingly, silica can rapidly dissolve in the processing liquid PL. Then, the processing liquid PL in the adjustment tank T2 is cooled to the second temperature that is relatively low and close to the temperature at which the substrate W is processed. Thus, the temperature of processing liquid PL in the adjustment tank T2 can be lowered rapidly, and the processing liquid PL at the desired temperature in which silica is dissolved can be obtained in a short time.

(2) The cooler D is the processing liquid supplier J, and the cooling controller 28 controls the processing liquid supplier J to supply the processing liquid PL lower than or equal to the second temperature to the adjustment tank T2. In the cooling process, the cooler D supplies the processing liquid PL at temperature lower than or equal to the second temperature to the adjustment tank T2. Thus, the processing liquid PL in the adjustment tank T2 can be rapidly cooled by supplying the processing liquid to the adjustment tank T2.

(3) The processing liquid supplier J includes the flow meter FM to measure the flow rate of the processing liquid PL supplied to the adjustment tank T2, and the cooling controller 28 controls the processing liquid supplier J to supply the processing liquid PL until the accumulated value of the flow rate that cools the processing liquid PL in the adjustment tank T2 to the second temperature is satisfied. Thus, the processing liquid PL of the flow rate required for cooling can be accurately supplied to the adjustment tank T2, and the processing liquid PL in the adjustment tank T2 can be surely cooled to the second temperature.

(4) The cooling controller 28 controls the processing liquid supplier J to supply the processing liquid PL at temperature lower than or equal the second temperature at the amount determined based on the first temperature, the difference between the first temperature and the second temperature, and the amount of the processing liquid PL in the adjustment tank T2 maintained at the first temperature. Thus, the processing liquid PL can be rapidly cooled to the second temperature by supplying the processing liquid PL at the temperature required for cooling at an amount appropriate according to the amount and temperature of the processing liquid PL in the adjustment tank T2.

(5) The silica supply controller 25 controls the silica supplier K to supply silica so that the concentration of silica contained in the processing liquid PL in the adjustment tank T2 becomes lower than the saturated solubility of silica at the temperature of the processing liquid PL supplied to the processing apparatus 100. Thus, the precipitation of silica before the processing liquid PL is supplied to the processing apparatus 100 after silica is supplied and dissolved in the processing liquid PL and after the cooling process can be suppressed.

(6) The processing liquid adjustment apparatus 1 includes the temperature sensor TS to measure the temperature of the processing liquid PL in the adjustment tank T2, and the heating controller 26 controls the heating unit H2 to heat the processing liquid PL in the adjustment tank T2 until the temperature of the processing liquid PL measured by the temperature sensor TS becomes the first temperature. Thus, the processing liquid PL in the adjustment tank T2 to which silica is supplied can be accurately heated to the first temperature at which silica easily dissolves.

### Second Embodiment

### Configuration

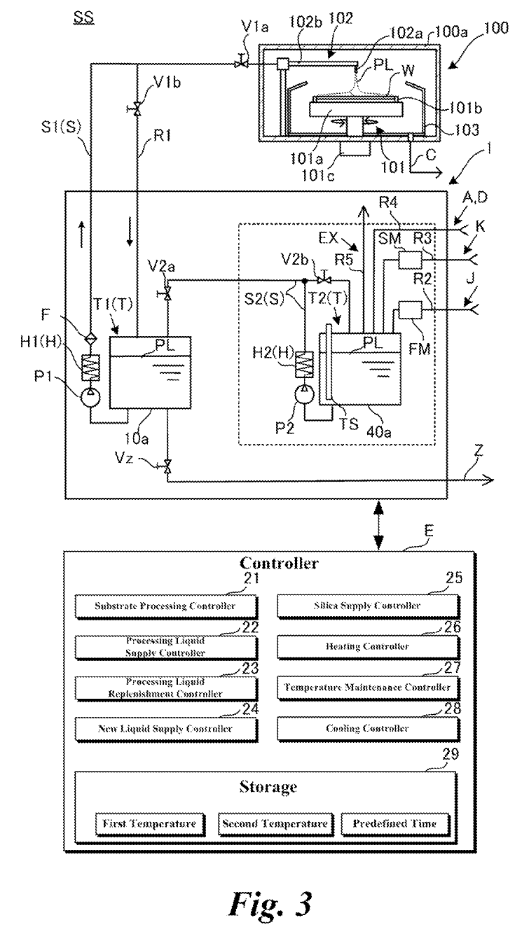

Next, the second embodiment is described. The second embodiment basically has the same configuration as the first embodiment. However, as illustrated in FIG. 3, a processing liquid adjustment apparatus 1 of the second embodiment includes a gas supply unit A that supplies gas to the liquid surface of the processing liquid PL in the adjustment tank T2. The gas supply unit A includes a gas supply piping R4 which has one end connected to an unillustrated gas supply source and which extends into the adjustment tank T2. The other end of the gas supply piping R4 is provided on the upper surface of the adjustment tank T2. Accordingly, gas can be supplied to the liquid surface of the processing liquid PL in the adjustment tank 2. The gas supply unit A forms the cooler D that lowers the temperature of the processing liquid PL in the adjustment tank T2. For example, the supplied gas is N₂ gas. Furthermore, it is preferable that the supplied gas is cooled beforehand. The temperature of the processing liquid PL is lowered by supplying the cooled gas to the liquid surface of the processing liquid PL in the adjustment tank T2 from the gas supply piping R4. Here, the cooling controller 28 controls the gas supply unit A to supply the gas until the temperature of the processing liquid PL measured by the temperature sensor TS becomes the second temperature.

Furthermore, the processing liquid adjustment apparatus 1 of the second embodiment includes a gas exhaustion unit EX that exhausts the gas in the adjustment tank T2. The gas exhaustion unit EX includes a gas exhaustion piping R5 which has one end connected to an unillustrated gas exhaustion device and the other end connected to the adjustment tank T2.

### Action

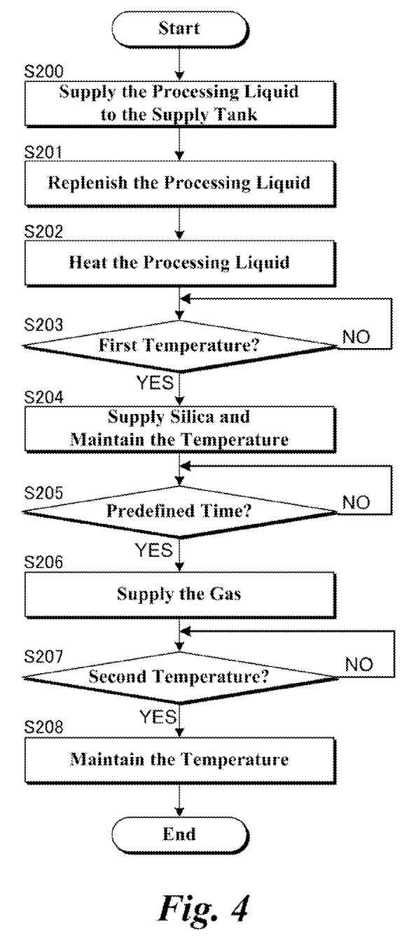

The action of the substrate processing apparatus SS of the above present embodiment is described referring to the flowchart of FIG. 4, in addition to FIG. 3. Note that the description about the same action as the first embodiment is omitted, and the different part from the first embodiment in the adjustment process of the processing liquid PL is mainly described.

Similarly to the above step S101, when the processing liquid PL in the adjustment tank T2 is supplied to the supply tank T1 (Step S200), the processing liquid PL at normal temperature is supplied from the new liquid piping R2 to replenish the processing liquid PL to the adjustment tank T2 (processing liquid supply process: Step S201). At this time, the total amount of the processing liquid PL that needs to be replenished is supplied. For example, when the total replenishment amount is 7.5 L, 7.5 L is supplied.

The valve V2a is closed and the valve V2b is opened, and the heating unit H2 heats the processing liquid PL circulating in the delivery piping S2 and the adjustment tank T2 (heating process: Step S202). Accordingly, the temperature of the processing liquid PL measured by the temperature sensor TS is raised to the first temperature (Step S203, NO).

When the temperature of the processing liquid PL is raised to the first temperature (Step S203, YES), the silica liquid is supplied to the processing liquid PL in the adjustment tank T2 from the addition piping R3 (silica supply process: Step S204). The heating unit H2 continues heating the processing liquid PL to maintain the first temperature until the predefined time required for silica supplied as the silica liquid to dissolve elapses (temperature maintenance process: Step S205, NO).

When the predefined time elapses (Step S205: YES), the cooled gas is supplied from the gas supply piping R4 to the adjustment tank T2 (cooling process: Step S206). The supplied gas may not be cooled if the processing liquid PL that has been heated to dissolve silica can be cooled to the second temperature that is close to the temperature to process the substrate W. The gas supplied to the processing liquid PL is exhausted from the gas exhaustion piping R5.

Accordingly, the temperature of the processing liquid PL measured by the temperature sensor TS is lowered to the second temperature by supplying the gas (Step S207, NO). Then, when the temperature of the processing liquid PL is lowered to the second temperature (Step S207, YES), the heating unit H2 maintains the temperature of the processing liquid PL circulating in the delivery piping S2 and the adjustment tank T2 at the second temperature until the processing liquid PL is delivered to the supply tank T1 as described above (Step S208).

### Effect

In the present embodiment, the cooler D is the gas supply unit A that supplies the gas to the processing liquid PL in the adjustment tank T2, and the cooling controller 28 controls the gas supply unit A to supply the gas to the processing liquid PL of the adjustment tank T2. Furthermore, in the cooling process, the cooler D supplies the gas to the processing liquid PL of the adjustment tank T2.

Thus, the temperature of the processing liquid PL in the adjustment tank T2 can be lowered to the second temperature by the gas. Furthermore, since vapor in the adjustment tank T2 is replaced with the gas, the evaporation of pure water contained in the processing liquid PL is facilitated, which facilitates concentration of the phosphoric acid solution that is the processing liquid PL so that the concentration of the phosphoric acid solution in the processing liquid PL can be adjusted.

Furthermore, in the present embodiment, the processing liquid adjustment apparatus 1 includes the temperature sensor TS to measure the temperature of the processing liquid PL in the adjustment tank T2, and the cooling controller 28 controls the cooler D to lower the temperature of the processing liquid PL in the adjustment tank T2 measured by the temperature sensor TS until the temperature of the processing liquid PL measured by the temperature sensor TS becomes the second temperature. Thus, the temperature of the processing liquid PL can be accurately lowered to the second temperature that is closed to the temperature to process the substrate W.

### Modified Example

The above embodiment may be implemented as the modified examples below.

(1) The temperature of the processing liquid PL is not limited to the above described values. For example, the first temperature is not limited to 162 °C. The first temperature is the temperature at which silica supplied to the processing liquid PL easily dissolves, and for example, is 155 to 170 °C. Furthermore, the second temperature is not limited to 147 °C. The second temperature is lower than the first temperature and is more than or equal the temperature to process the substrate W, and for example is 140 to 150 °C. If the difference between the first temperature and the second temperature changes by changing the target temperature for the first temperature and the second temperature, the processing liquid PL may be supplied to lower the temperature of the processing liquid PL by said temperature difference. The processing liquid PL supplied by the processing liquid supplier J may not be at normal temperature. For example, if the processing liquid PL is supplied before the heating process, the processing liquid PL at temperature higher than normal temperature may be supplied. Accordingly, the temperature of the processing liquid PL can be raised to the first temperature in a short time.

(2) The cooler D may be a cooling device provided in the middle of the delivery piping S2 that circulates the processing liquid PL of the adjustment tank T2. For example, cooling devices with peltier elements may be used. The cooling device can cool the processing liquid PL flowing in the delivery piping S2 by cooling the delivery piping S2.

(3) The heating unit H2 may be provided in the adjustment tank T2. Furthermore, the processing liquid adjustment apparatus 1 may include a concentration meter to measure the concentration of silica. For example, a concentration meter to measure the concentration of silica in the processing liquid PL in the adjustment tank T2 may be provided. In this case, the concentration of silica contained in the processing liquid PL that has been cooled to the second temperature by the cooling process is measured and the processing liquid PL can be newly supplied by the processing liquid supplier J based on the measurement result, so that the concentration of silica in the processing liquid PL in the adjustment tank T2 appropriate for processing the substrate W can be accurately achieved.

(4) Although the temperature sensor TS is provided in the adjustment tank T2 in the above aspect, it is not limited thereto. For example, the temperature sensor TS may be provided in the middle of the delivery piping S2 and may measure the temperature of the processing liquid PL in the adjustment tank T2 by measuring the temperature of the processing liquid PL flowing in the delivery piping S2.

(5) The order to adjust the processing liquid PL is not limited to the above example. For example, the new liquid may be supplied after the silica liquid is supplied to the adjustment tank T2, or the silica liquid and the new liquid may be supplied at the same time.

(6) Although the addition piping R3 is connected to the adjustment tank T2, the addition piping R3 may be connected to the middle of the new liquid piping R2. In this case, it is preferable to connect the addition piping R3 downstream of the flow meter FM to measure the flow rate of the processing liquid PL. Accordingly, silica supplied from the addition piping R3 is supplied to the adjustment tank T2 via the new liquid piping R2. According to this configuration, silica that has flowed into the new liquid piping R2 can be flushed to the adjustment tank T2 by the new liquid when the new liquid is supplied after silica is supplied or when the new liquid and silica are supplied at the same time. This prevents silica from remaining in the new liquid piping R2, and silica can be supplied in an accurate amount.

(7) the processing liquid adjustment apparatus 1 may be configured with both the cooler D of the first embodiment and the cooler D of the second embodiment. That is, in the cooling process, the cooling time may be shortened by supplying the processing liquid PL and the gas.

(8) Although the total replenishment amount of the processing liquid PL is 7.5 L, it is not limited thereto. If the total replenish amount of the processing liquid PL is changed, the supply amount of the processing liquid PL in the cooling process is set in advance so that the temperature of the processing liquid PL is lowered to the second temperature by supplying the processing liquid PL to the adjustment tank T2 in the cooling process.

(9) Although the gas supply unit A supplies the gas to the liquid surface of the processing liquid PL in the adjustment tank T2, it is not limited thereto. For example, the gas supply unit A may supply the gas to the processing liquid PL in the adjustment tank T2. In this case, the other end of the gas supply piping R4 may be provided at the bottom surface of the adjustment tank T2.

(10) The substrate processing apparatus SS may be configured to circulate the processing liquid PL between the processing liquid adjustment apparatus 1 and the processing apparatus 100. For example, the collection piping C may be provided to deliver the processing liquid PL from the processing apparatus 100 to the supply tank T1 or the adjustment tank T2 of the processing liquid adjustment apparatus 1. Accordingly, the substrate processing apparatus SS can circulate the processing liquid PL between the processing liquid adjustment apparatus 1 and the processing apparatus 100.

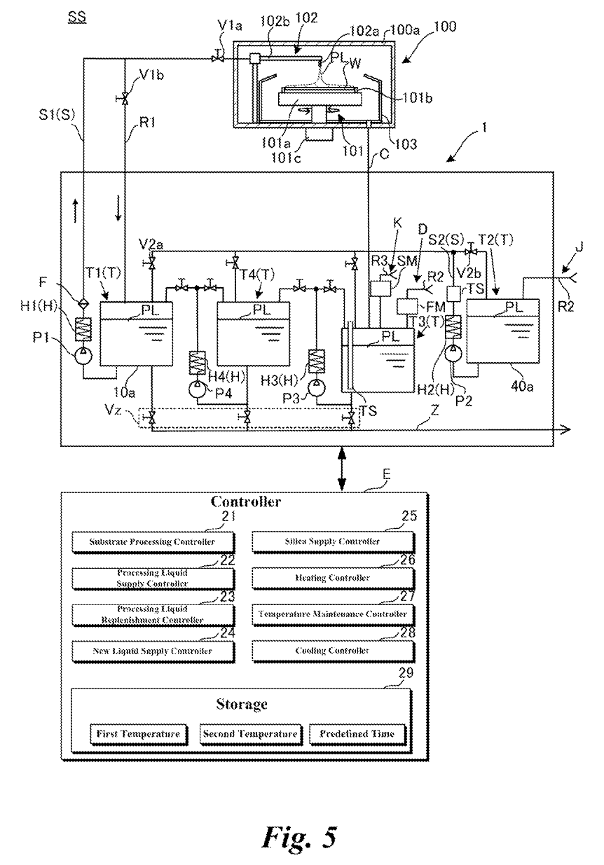

(11) As described above, for example, as illustrated in FIG. 5, in the processing liquid adjustment apparatus 1 including a collection tank T3 to store the processing liquid PL collected from the processing apparatus 100 via a collection piping C and a buffer tank T4 to temporarily store the processing liquid PL from the collection tank T3 and supply the processing liquid PL to the supply tank T1, the collection tank T3 may be implemented as the tank T for dissolving silica and cooling the processing liquid PL.

FIG. 5 is an example in which the collection tank T3 functions as the adjustment tank by providing the silica supplier K, the cooler D and the temperature sensor TS to the collection tank T3 like the first embodiment. The collection tank T3 has a circulation path provided with a pump P3 and a heating unit H3 that is the heater. Also in this case, the processing liquid PL of the collection tank T3 heated by the heating unit H3 can be cooled by supplying silica from the silica supplier K and the new liquid supplied from the new liquid piping R2 forming the cooler D to the processing liquid PL. Note that the gas supply piping R4 as the cooler D and the gas exhaustion piping R5 as the gas exhaustion unit EX may be provided to the collection tank T3, like the second embodiment. Furthermore, both the first embodiment and the second embodiment may be applied to the collection tank T3.

Furthermore, the first embodiment, the second embodiment, or both the first embodiment and the second embodiment may be applied to the buffer tank T4 including the circulation path provided with the pump P4 and the heating unit H4.

Note that the supply tank T1 may be omitted and the adjusted processing liquid PL may be directly supplied to the processing apparatus 100 from the adjustment tank T2.

(12) The processing apparatus 100 to supply the processing liquid PL to the substrate W is not limited to the single-wafer type and may be a batch type. However, the present disclosure is suitable for the single-wafer type processing apparatus 100 in which the processing liquid PL must be supplied to the substrate W with the parameters that affect the processing constant, whereas the batch type processing apparatus in which the substrate W is immersed in the processing liquid after adjusting the parameters of the processing liquid such as temperature and concentration over time in the processing tank before the processing.

### Other Embodiment

As above, although the modified examples of the embodiments and portions according to the present disclosure are described, these modified examples of the embodiments and portions are only presented as examples and are not intended to limit the scope of the claims. These new embodiments described above can be implemented in other various forms, and various omissions, replacements, modifications, and changes may be performed without departing from an abstract of the invention. These embodiments and modification thereof are included in the scope and abstract of the invention, and are included in the invention described in the scope of the claims.

### REFERENCE SIGN

1: processing liquid adjustment apparatus

10a: container

21: substrate processing controller

22: processing liquid supply controller

23: processing liquid replenishment controller

24: new liquid supply controller

25: silica supply controller

26: heating controller

27: temperature maintenance controller

28: cooling controller

29: storage

40a: container

100: processing apparatus

100a: chamber

101: rotation unit

101a: rotation body

101b: holding unit

101c: drive source

102: supplying unit

102a: nozzle

102b: arm

103: collection unit

A: gas supply unit

C: collection piping

D: cooler

E: controller

EX: gas exhaustion unit

F: filter

FM, SM: flow meter

H: heater

H1-H4: heating unit

J: processing liquid supplier

K: silica supplier

P1-P4: pump

PL: processing liquid

R1: return piping

R2: new liquid piping

R3: addition piping

R4: gas supply piping

R5: gas exhaustion piping

S: supply path

S1: supply piping

S2: delivery piping

SS: substrate processing apparatus

T: tank

T1: supply tank

T2: adjustment tank

T3: collection tank

T4: buffer tank

TS: temperature sensor

V1a-V2b, Vz: valve

W: substrate

Z: discharge path

What is claimed is:

1. A processing liquid adjustment apparatus that adjusts a processing liquid supplied to a processing apparatus that processes a substrate using a phosphoric acid solution that is the processing liquid, the processing liquid adjustment apparatus comprising:
an adjustment tank that stores the processing liquid;
a processing liquid supplier that supplies the processing liquid to the adjustment tank;
a heater that heats the processing liquid;
a silica supplier that supplies silica to the processing liquid in the adjustment tank;
a cooler that lowers a temperature of the processing liquid in the adjustment tank; and
a controller that controls the processing liquid supplier, the heater, the silica supplier and the cooler,
wherein the controller includes:
a new liquid supply controller that controls the processing liquid supplier to supply the processing liquid to the adjustment tank,
a silica supply controller that controls the silica supplier to supply silica to the processing liquid in the adjustment tank,
a heating controller that controls the heater to raise the temperature of the processing liquid in the adjustment tank to a first temperature,
a temperature maintenance controller that controls the heater to maintain the temperature of processing liquid in the adjustment tank to which the silica has been supplied at the first temperature, and
a cooling controller that controls the cooler to lower the temperature of the processing liquid in the adjustment tank to a second temperature that is lower than the first temperature after a maintenance of the first temperature by the temperature maintenance controller.

2. The processing liquid adjustment apparatus according to claim 1, wherein:
the cooler is the processing liquid supplier, and
the cooling controller controls the processing liquid supplier to supply the processing liquid at temperature lower than or equal to the second temperature to the adjustment tank.

3. The processing liquid adjustment apparatus according to claim 1, wherein:
the cooler is a gas supplier that supplies gas to the processing liquid in the adjustment tank, and
the cooling controller controls the gas supplier to supply the gas to the processing liquid in the adjustment tank.

4. The processing liquid adjustment apparatus according to claim 2, wherein:
the processing liquid supplier includes a flow meter to measure a flow rate of the processing liquid supplied to the adjustment tank, and
the cooling controller controls the processing liquid supplier to supply the processing liquid until an accumulated value of the flow rate reaches a value that cools the processing liquid in the adjustment tank to the second temperature.

5. The processing liquid adjustment apparatus according to claim 2, wherein the cooling controller controls the processing liquid supplier to supply the processing liquid at temperature lower than or equal to the second temperature at an amount determined based on the first temperature, a difference between the first temperature and the second temperature, and an amount of the processing liquid in the adjustment tank maintained at the first temperature.

6. The processing liquid adjustment apparatus according to claim 1, wherein the silica supply controller controls the silica supplier to supply the silica so that a concentration of the silica contained in the processing liquid in the adjustment tank becomes lower than a saturated solubility of the silica at a temperature of the processing liquid supplied to the processing apparatus.

7. The processing liquid adjustment apparatus according to claim 1, further comprising a temperature sensor to measure the temperature of the processing liquid in the adjustment tank,
wherein the heating controller controls the heater to raise the temperature of the processing liquid in the adjustment tank measured by the temperature sensor to the first temperature.

8. The processing liquid adjustment apparatus according to claim 1, further comprising a temperature sensor to measure the temperature of the processing liquid in the adjustment tank,
wherein the cooling controller controls the cooler to lower the temperature of the processing liquid in the adjustment tank measured by the temperature sensor to the second temperature.

9. A substrate processing apparatus comprising:
the processing liquid adjustment apparatus according to claim 1; and
the processing apparatus.

10. A processing liquid adjustment method for adjusting a processing liquid supplied to a processing apparatus that processes a substrate using a phosphoric acid solution that is the processing liquid, the processing liquid adjustment method comprising:
a processing liquid supply process of supplying the processing liquid to an adjustment tank;
a heating process of raising a temperature of the processing liquid in the adjustment tank to a first temperature;
a silica supply process of supplying silica to the processing liquid in the adjustment tank;
a temperature maintenance process of maintaining the temperature of the processing liquid in the adjustment tank to which the silica has been supplied at the first temperature; and
a cooling process of lowering the temperature of the processing liquid in the adjustment tank to a second temperature that is lower than the first temperature by a cooler after the temperature maintenance process.

11. The processing liquid adjustment method according to claim 10, wherein in the cooling process, the processing liquid at the temperature lower than or equal to the second temperature is supplied to the adjustment tank by the cooler.

12. The processing liquid adjustment method according to claim 10, wherein in the cooling process, a gas is supplied to the processing liquid in the adjustment tank by the cooler.
